(19) United States
(12) Patent Application Publication
(10) Pub. No.: US 2026/0058097 A1
(43) Pub. Date: Feb. 26, 2026

(54) PLASMA PROCESSING APPARATUS

(71) Applicant: TOKYO ELECTRON LIMITED, Tokyo (JP)

(72) Inventor: Masaki HIRAYAMA, Tokyo (JP)

(21) Appl. No.: 19/299,283

(22) Filed: Aug. 13, 2025

(30) Foreign Application Priority Data
Aug. 21, 2024 (JP) 2024-139626

(51) Int. Cl. H01J 37/32

(52) U.S. Cl. CPC H01J 37/32183

(57) ABSTRACT

A plasma processing apparatus includes: a chamber; an introducer disposed to introduce electromagnetic waves into a plasma generation region in the chamber; a radio-frequency power source; a radio-frequency supply line electrically connected to the radio-frequency power source; and a resonator including a power feeder which is an entrance of electromagnetic waves and is connected to the radio-frequency supply line, first and second ends resonating the electromagnetic waves therebetween, and a waveguide extending between the first and second ends to be electromagnetically coupled to the introducer, wherein a distance between the power feeder and the first end along a propagation direction of the electromagnetic waves is shorter than a distance along the propagation direction between the first end and a position in the resonator at which, during plasma excitation, an impedance obtained when viewing a load side from the position becomes equal to characteristic impedance of the radio-frequency supply line.

### CROSS-REFERENCE TO RELATED APPLICATION

This application is based upon and claims the benefit of priority from Japanese Patent Application No. 2024-139626, filed on Aug. 21, 2024, the entire contents of which are incorporated herein by reference.

### TECHNICAL FIELD

An embodiment of the present disclosure relates to a plasma processing apparatus.

### BACKGROUND

Plasma processing apparatuses are used in plasma processing on a substrate. A plasma processing apparatus includes a chamber, a radio-frequency power source, a resonator, an introducer, and a matcher. The radio-frequency power source is coupled to the resonator. Electromagnetic waves from the resonator are supplied into the chamber from the introducer. The matcher is connected between the radio-frequency power source and the resonator. Such a plasma processing apparatus is described in the following Patent Document 1.

### PRIOR ART DOCUMENTS

### Patent Documents

Patent Document 1: Japanese Patent Laid-Open Publication No. 2020-92031

### SUMMARY

According to an embodiment of the present disclosure, there is provided a plasma processing apparatus. The plasma processing apparatus includes a chamber, an introducer, a radio-frequency power source, a radio-frequency supply line, and a resonator. The introducer is disposed to introduce electromagnetic waves into a plasma generation region in the chamber. The radio-frequency supply line is electrically connected to the radio-frequency power source. The resonator includes a power feeder, a first end, a second end, and a waveguide. The power feeder is an entrance of electromagnetic waves in the resonator and is connected to the radio-frequency supply line. The waveguide extends between the first end and the second end, which are configured to resonate the electromagnetic waves therebetween, and is electromagnetically coupled to the introducer. A distance between the power feeder and the first end along a propagation direction of the electromagnetic waves is shorter than a distance along the propagation direction between the first end and a position in the resonator at which, during plasma excitation, an impedance obtained when viewing a load side from the position becomes equal to a characteristic impedance of the radio-frequency supply line.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a view illustrating a plasma processing apparatus according to an exemplary embodiment of the present disclosure.

FIG. 2 is a view illustrating a lower portion in a resonator of a plasma processing apparatus according to an exemplary embodiment of the present disclosure.

FIG. 3 is a view illustrating an example of a relationship between a position in a resonator in a propagation direction and a voltage.

FIG. 4 is a view illustrating an example of a capacitor that can be employed in a plasma processing apparatus according to an exemplary embodiment of the present disclosure.

FIG. 5 is a view illustrating another example of a capacitor that can be employed in a plasma processing apparatus according to an exemplary embodiment of the present disclosure.

FIG. 6 is a view illustrating a plasma processing apparatus according to another exemplary embodiment of the present disclosure.

FIG. 7 is a view illustrating a plasma processing apparatus according to yet another exemplary embodiment of the present disclosure.

FIG. 8 is a view illustrating a coupler according to an exemplary embodiment of the present disclosure.

FIG. 9 is a cross-sectional view illustrating a coupler according to another exemplary embodiment of the present disclosure.

FIG. 10 is a cross-sectional view taken along line X-X of FIG. 9.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Various exemplary embodiments are described below in detail with reference to the drawings. In addition, the same or equivalent parts are designated by like reference numerals in each drawing.

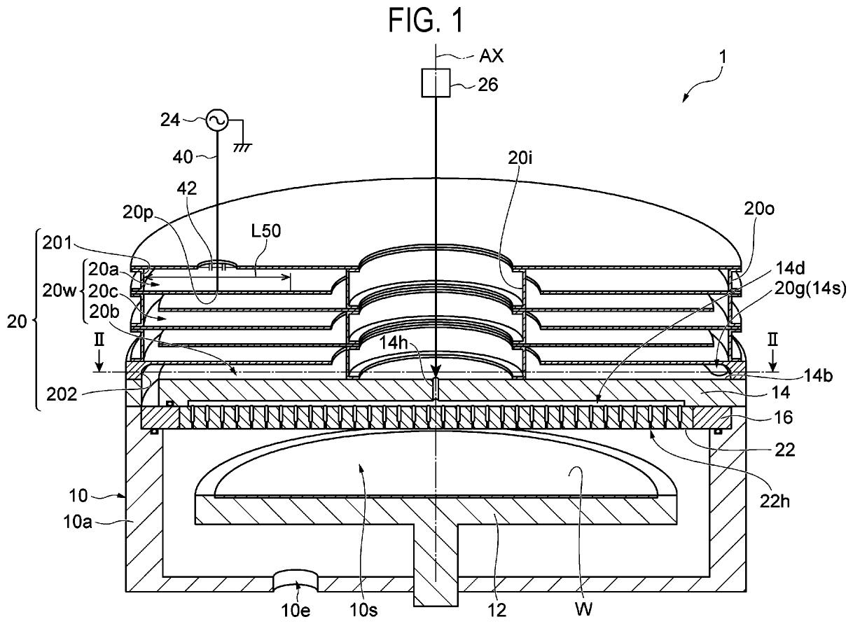

FIG. 1 is a view illustrating a plasma processing apparatus according to an exemplary embodiment of the present disclosure. A plasma processing apparatus 1 illustrated in FIG. 1 includes a chamber 10, a substrate support 12, an introducer 16, a resonator 20, and a radio-frequency power source 24.

The chamber 10 provides a processing space 10s therein. In the plasma processing apparatus 1, a substrate W is processed in the processing space 10s. The chamber 10 is formed of a metal such as aluminum, and is grounded. The chamber 10 has a sidewall 10a and is opened at an upper end thereof. The chamber 10 and the sidewall 10a may have a substantially cylindrical shape. The processing space 10s is provided inside the sidewall 10a. A central axis line of each of the chamber 10, the sidewall 10a, and the processing space 10s is an axis line AX. The chamber 10 may have a corrosion-resistant film on its surface. The corrosion-resistant film may be an yttrium oxide film, an yttrium oxyfluoride film, an yttrium fluoride film, or a ceramic film containing yttrium oxide, yttrium fluoride, or the like.

A bottom portion of the chamber 10 is provided with an exhaust port 10e. An exhaust device is connected to the exhaust port 10e. The exhaust device may include a vacuum pump such as a dry pump and/or a turbo molecular pump, and an auto pressure control valve.

The substrate support 12 is provided in the processing space 10s. The substrate support 12 is configured to substantially horizontally support the substrate W placed on its upper surface. The substrate support 12 has a substantially disc shape. A central axis line of the substrate support 12 is the axis line AX.

In an embodiment, the plasma processing apparatus 1 may further include an upper electrode 14. The upper electrode 14 is provided above the substrate support 12 via the processing space 10s. The upper electrode 14 is formed of a conductor such as a metal (e.g., aluminum), and has a substantially disc shape. A central axis line of the upper electrode 14 is the axis line AX. The upper electrode 14 constitutes an excitation electrode together with a shower plate 22 which will be described later.

The introducer 16 is provided to radiate electromagnetic waves into a plasma generation region therefrom. In the plasma processing apparatus 1, the plasma generation region is a space in the processing space 10s and immediately below the excitation electrode, i.e., immediately below the shower plate 22. In the plasma processing apparatus 1, by electromagnetic waves radiated into the plasma generation region from the introducer 16, a gas in the plasma generation region is excited to generate plasma. The electromagnetic waves radiated into the plasma generation region from the introducer 16 may be radio-frequency waves such as VHF waves or UHF waves. The introducer 16 is formed of a dielectric material such as quartz, aluminum nitride, or aluminum oxide. In an embodiment of the present disclosure, the introducer 16 is provided at a lateral end portion of the processing space 10s, and extends in a circumferential direction around the axis line AX. The introducer 16 may have an annular shape.

The resonator 20 includes a power feeder 20p and a waveguide 20w. The power feeder 20p is an entrance of electromagnetic waves to the waveguide 20w of the resonator 20. The electromagnetic waves are generated based on radio-frequency power generated by the radio-frequency power source 24. The radio-frequency power source 24 may be configured to be capable of changing a frequency of output radio-frequency power. The radio-frequency power source 24 and the power feeder 20p are electrically connected via a radio-frequency supply line 40. The electromagnetic waves are input to the power feeder 20p of the resonator 20 via the radio-frequency supply line 40. The resonator 20 resonates the electromagnetic waves input to the power feeder 20p in the waveguide 20w and propagates the electromagnetic waves to the introducer 16. The electromagnetic waves are introduced into the plasma generation region from the introducer 16. In an embodiment of the present disclosure, the resonator 20 may be provided above the chamber 10 and on the upper electrode 14.

In an embodiment of the present disclosure, the plasma processing apparatus 1 may further include the shower plate 22. The shower plate 22 may be formed of a metal such as aluminum. The introducer 16 extends to surround the shower plate 22. The introducer 16 and the shower plate 22 are arranged to close an upper end opening of the chamber 10. The shower plate 22 is provided with a plurality of gas holes 22h. The plurality of gas holes 22h extend in a thickness direction (vertical direction) of the shower plate 22 and penetrate the shower plate 22.

The shower plate 22 is provided below the upper electrode 14. The shower plate 22 extends on the above-described plasma generation region. The shower plate 22 and the upper electrode 14 define a gas diffusion space 14d therebetween. A central axis line of the gas diffusion space 14d may be the axis line AX. The plurality of gas holes 22h of the shower plate 22 are connected to the gas diffusion space 14d. Further, the upper electrode 14 is provided with an entrance 14h. The entrance 14h may extend on the axis line AX. The entrance 14h is connected to the gas diffusion space 14d. A gas supply 26 is connected to the gas diffusion space 14d. A gas output from the gas supply 26 is supplied into the processing space 10s via the entrance 14h, the gas diffusion space 14d, and the plurality of gas holes 22h.

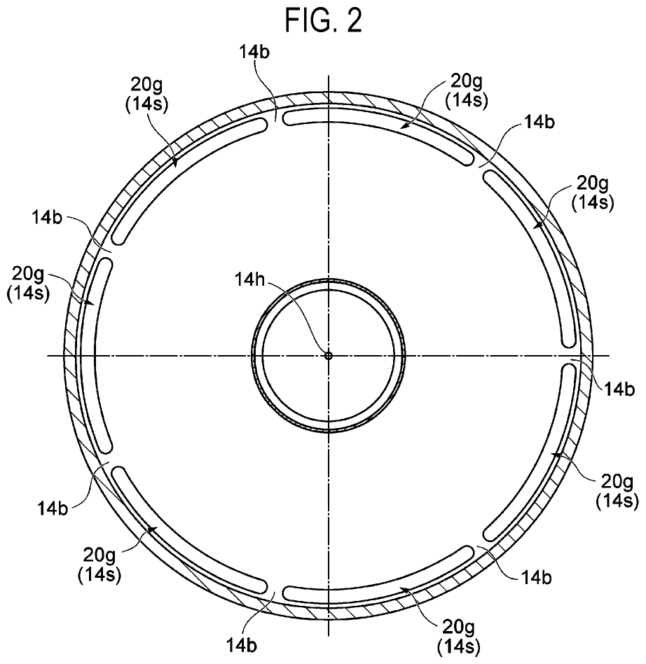

Hereinafter, reference is made to FIG. 2 together with FIG. 1. FIG. 2 is a view illustrating a lower portion in the resonator of the plasma processing apparatus according to the exemplary embodiment. FIG. 2 is a cross-sectional view taken along line II-II of FIG. 1. The waveguide 20w of the resonator 20 may provide a cavity surrounded by a wall. A wall of the waveguide 20w is formed of a material such as a metal. The wall of the waveguide 20w may be formed of an aluminum alloy, copper, nickel, stainless steel or the like, and may be covered with a low resistance material such as silver, gold, or rhodium.

The resonator 20 includes a first end 201 and a second end 202. The first end 201 and the second end 202 constitute one end portion and the other end portion of the waveguide 20w of the resonator 20. The waveguide 20w extends between the first end 201 and the second end 202, and is electromagnetically coupled to the introducer 16.

In an embodiment of the present disclosure, a wall of the resonator 20 may include an inner periphery 20i and an outer periphery 200. The inner periphery 20i extends around the axis line AX which is a central axis line thereof, and has a substantially cylindrical shape. The outer periphery 200 extends coaxially with the inner periphery 20i around the axis line AX. The outer periphery 200 may have a substantially cylindrical shape.

The waveguide 20w may have a layered structure alternately folded between the inner periphery 20i and the outer periphery 200. The wall of the waveguide 20w may include a plurality of walls extending radially and circumferentially between adjacent layers of the layered structure and between the inner periphery 20i and the outer periphery 200. The plurality of walls may be annular plates.

Further, the waveguide 20w may include an upper portion 20a constituting an uppermost layer of the layered structure and a lower portion 20b constituting a lowermost layer of the layered structure. Further, the layered structure may include a middle portion 20c between the upper portion 20a and the lower portion 20b. In the present embodiment, the upper portion 20a may provide the first end 201, i.e., an upper end of the waveguide 20w in the outer periphery 200. In this case, the first end 201 of the waveguide 20w extends circumferentially around the axis line AX. Further, the lower portion 20b may provide the second end 202, i.e., a lower end of the waveguide 20w in the outer periphery 200. In this case, the second end 202 of the waveguide 20w extends circumferentially around the axis line AX.

The resonator 20 provides a plurality of gaps 20g in the vicinity of the second end 202 or along the second end 202. The plurality of gaps 20g are arranged circumferentially around the axis line AX. Electromagnetic waves resonating in the resonator 20 are electronically propagated to the introducer 16 via the plurality of gaps 20g.

In an embodiment of the present disclosure, the upper electrode 14 provides a plurality of slots 14s as the plurality of gaps 20g, and includes a plurality of beams 14b. The plurality of slots 14s are arranged above the introducer 16. The plurality of slots 14s electromagnetically couple the waveguide 20w and the introducer 16 to each other. The plurality of slots 14s penetrate the upper electrode 14 along a thickness direction (vertical direction) thereof, and elongate circumferentially. The plurality of slots 14s are spaced apart from each other, and are arranged circumferentially around the axis line AX. The plurality of slots 14s may be arranged at equal intervals. The plurality of beams 14b are alternately arranged with the plurality of slots 14s circumferentially around the axis line AX. The plurality of beams 14b connect an inner portion and an outer portion of the upper electrode 14 to each other.

In the plasma processing apparatus 1, resonance of electromagnetic waves is generated between the first end 201 and the second end 202 of the resonator 20. The electromagnetic waves resonating in the resonator 20 are supplied to the introducer 16 via the plurality of gaps 20g, i.e., the plurality of slots 14s. The electromagnetic waves supplied to the introducer 16 are radiated into the plasma generation region from the introducer 16.

As illustrated in FIG. 1, in the plasma processing apparatus 1, a distance between the power feeder 20p and the first end 201 along a propagation direction (diameter direction or opposite direction thereof) of electromagnetic waves is shorter than a distance L50. The distance L50 is a distance along the propagation direction between the first end 201 and a position in the resonator 20 at which, during plasma excitation, an impedance obtained when viewing a load side from the position becomes equal to a characteristic impedance of the radio-frequency supply line 40.

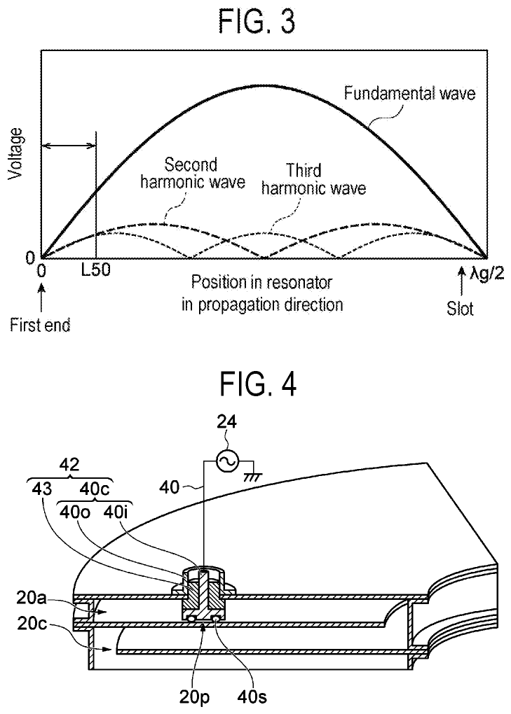

FIG. 3 is a view illustrating an example of a relationship between a position in a propagation direction in the resonator and a voltage. The horizontal axis of FIG. 3 represents a position in a propagation direction of an electromagnetic wave in the resonator. In the resonator 20, the second end 202 is spaced apart from the first end 201 by a distance of λg/2 along a propagation direction of the electromagnetic wave. λg is a wavelength (i.e., a waveguide wavelength) of the electromagnetic wave (fundamental wave) in the resonator 20. The vertical axis of FIG. 3 represents a voltage of each of a fundamental wave and harmonic waves of the electromagnetic wave in the resonator 20. As illustrated in FIG. 3, a voltage of a harmonic wave at a position, at which a distance from the first end 201 is smaller than the distance L50, is lower than a voltage of a harmonic wave at a position, at which a distance from the first end 201 is the distance L50. As described above, in the plasma processing apparatus 1, the distance between the power feeder 20p and the first end 201 is shorter than the distance L50, and hence a voltage of a harmonic wave in the power feeder 20p is low. Thus, it is possible for the plasma processing apparatus 1 to suppress harmonic waves returning to the radio-frequency power source 24. Accordingly, in the plasma processing apparatus 1, it is possible to suppress influences such as loss of radio-frequency power and abnormal oscillations in the radio-frequency power source.

In an embodiment of the present disclosure, in order to suppress reflection of radio-frequency power, which is caused by a difference between an impedance obtained when viewing a load side from the power feeder 20p and a characteristic impedance of the radio-frequency supply line 40, the plasma processing apparatus 1 may include at least one capacitor 42. The at least one capacitor 42 may form an electrostatic capacity between an inner conductor and an outer conductor of a coaxial line included in the radio-frequency supply line 40.

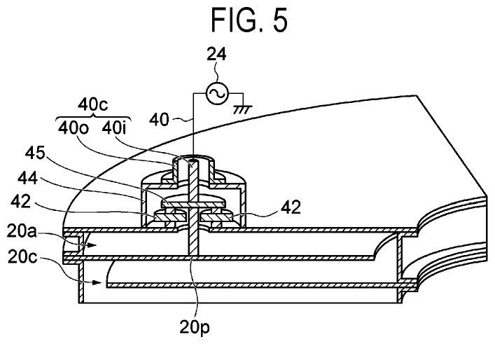

Some examples of the at least one capacitor 42 are described below with reference to FIGS. 4 and 5. FIG. 4 is a view illustrating an example of a capacitor that can be employed in a plasma processing apparatus according to an exemplary embodiment of the present disclosure. FIG. 5 is a view illustrating another example of a capacitor that can be employed in a plasma processing apparatus according to an exemplary embodiment of the present disclosure.

As illustrated in FIG. 4, the radio-frequency supply line 40 may include a coaxial connector 40c which is a coaxial line. The coaxial connector 40c includes an inner conductor 40i and an outer conductor 400. The outer conductor 400 has a cylindrical shape and surrounds the inner conductor 40i. The inner conductor 40i and the outer conductor 400 extend coaxially. A lower end of the inner conductor 40i is electrically connected to the power feeder 20p. In an embodiment of the present disclosure, the lower end of the inner conductor 40i is electrically connected to a wall of the resonator 20, which defines the upper portion 20a from below. The lower end of the inner conductor 40i may be electrically connected to the power feeder 20p via an electric body 40s (e.g., a spring member) formed of a conductor. Further, the outer conductor 400 is electrically connected to a wall of the resonator 20, which defines the upper portion 20a from above. A dielectric member 43 is disposed between the inner conductor 40i and the outer conductor 400. The dielectric member 43 may have a cylindrical shape. The dielectric member 43 is formed of, for example, polytetrafluoroethylene. In the example illustrated in FIG. 4, the inner conductor 40i, the outer conductor 400, and the dielectric member 43 constitute a capacitor 42.

In the example illustrated in FIG. 5, an outer conductor 400 is electrically connected to the wall of the resonator 20, which defines the upper portion 20a from above, via a cylindrical cover 44. Further, an inner conductor 40i is formed in a rod shape, and includes a power distribution plate 45 between an upper end and a lower end thereof. The power distribution plate 45 is disposed in the cover 44. In the example illustrated in FIG. 5, a plurality of capacitors 42 (e.g., ceramic condensers) are connected in parallel between the power distribution plate 45 and the wall of the resonator 20, which defines the upper portion 20a from the above. Accordingly, the plurality of capacitors 42 are connected in parallel between the inner conductor 40i and the outer conductor 400. The plurality of capacitors 42 are disposed in the cover 44. The plurality of capacitors 42 may be arranged circumferentially around a rod-shaped portion of the inner conductor 40i. The plurality of capacitors 42 may be arranged at equal intervals around the rod-shaped portion of the inner conductor 40i.

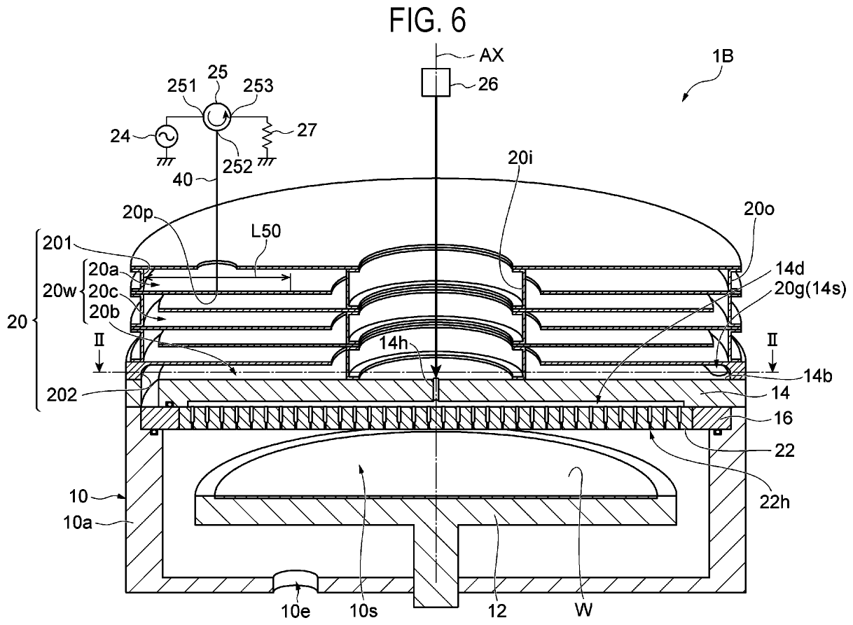

A plasma processing apparatus according to another exemplary embodiment of the present disclosure is described below with reference to FIG. 6. FIG. 6 is a view illustrating the plasma processing apparatus according to another exemplary embodiment. A plasma processing apparatus 1B illustrated in FIG. 6 is described below in terms of differences from the plasma processing apparatus 1.

The plasma processing apparatus 1B does not include the capacitor 42 but further includes a circulator 25. The circulator 25 includes a first port 251, a second port 252, and a third port 253. The circulator 25 outputs radio-frequency power (travelling waves) received at the first port 251 from the second port 252, and outputs radio-frequency power (reflected waves) received at the second port 252 from the third port 253. The radio-frequency power source 24 is connected to the first port 251. The second port 252 is connected to the power feeder 20p via the radio-frequency supply line 40. A load 27 is connected to the third port 253. According to the plasma processing apparatus 1B, the reflected waves of the radio-frequency power are returned to the load 27 by the circulator 25. Thus, the reflected waves are suppressed from being returned to the radio-frequency power source 24. Further, the plasma processing apparatus 1B may include, instead of the circulator 25, an isolator configured to output radio-frequency power from the radio-frequency power source 24 to the power feeder 20p via the radio-frequency supply line 40 and output reflected waves of the radio-frequency power to the load 27.

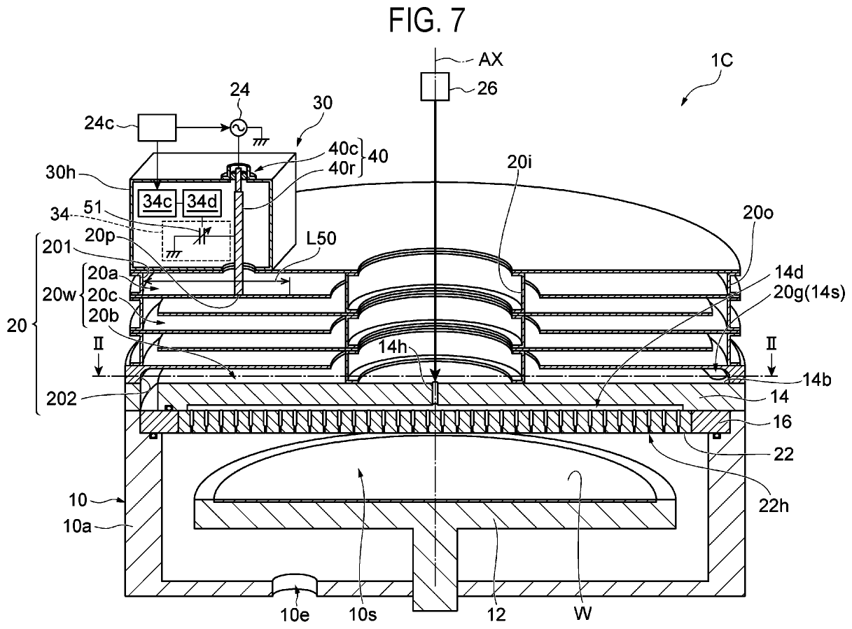

A plasma processing apparatus according to another exemplary embodiment of the present disclosure is described below with reference to FIG. 7. FIG. 7 is a view illustrating the plasma processing apparatus according to another exemplary embodiment of the present disclosure. A plasma processing apparatus 1C illustrated in FIG. 7 is described below in terms of differences from the plasma processing apparatus 1.

The plasma processing apparatus 1C does not include the capacitor 42 but includes a coupler 30. The radio-frequency power source 24 is electrically connected to the power feeder 20p via the coupler 30 and the radio-frequency supply line 40. In the plasma processing apparatus 1C, the radio-frequency supply line 40 may include a coaxial connector 40c and a coupling rod 40r. The coupling rod 40r is connected to an inner conductor of the coaxial connector 40c, and is connected to the radio-frequency power source 24 via the coaxial connector 40c.

The coupler 30 includes a matching circuit 34. The matching circuit 34 is disposed in a grounded housing 30h (e.g., a metal housing). The matching circuit 34 has a variable impedance. The matching circuit 34 is connected between the coupling rod 40r and a ground. The matching circuit 34 includes a variable capacitor 51 configured to provide the variable impedance.

The coupler 30 further includes a driver 34d and a controller 34c. The driver 34d is configured to drive the matching circuit 34 so as to adjust the variable impedance of the matching circuit 34. The controller 34c is configured to adjust the impedance of the matching circuit 34 by controlling the driver 34d. The controller 34c includes a control circuit and a communication circuit. The control circuit of the controller 34c may be constituted by a programmable processor such as a CPU or an MPU, a programmable logic device such as a field programmable gate array (FPGA), or a dedicated circuit such as an application specific integrated circuit (ASIC).

In an embodiment of the present disclosure, the plasma processing apparatus 1C may further include a directional coupler and a power controller 24c. The directional coupler may be provided in the radio-frequency power source 24 or between the radio-frequency power source 24 and an input unit of radio-frequency power in the coupler 30. The power controller 24c may be configured as a programmable processor such as a CPU or an MPU, a programmable logic device such as a field programmable gate array (FPGA), or a dedicated circuit such as an application specific integrated circuit (ASIC).

The directional coupler outputs a signal that reflects a power level of reflected waves of radio-frequency power to the power controller 24c. The power controller 24c controls the radio-frequency power source 24 or the matching circuit 34 to reduce the power level of the reflected waves according to the signal from the directional coupler. To reduce the power level of the reflected waves, the power controller 24c may control the radio-frequency power source 24 to adjust a frequency of the radio-frequency power. Instead of this or in addition to this, the power controller 24c may adjust the variable impedance of the matching circuit 34 by communicating with the controller 34c so as to reduce the power level of the reflected waves.

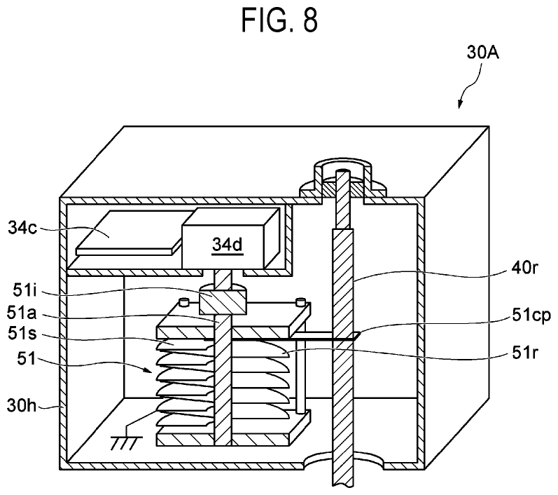

Hereinafter, reference is made to FIG. 8 together with FIG. 7. FIG. 8 is a view illustrating a coupler according to an exemplary embodiment of the present disclosure. A coupler 30A illustrated in FIG. 8 may be used as the coupler 30 of the plasma processing apparatus 1C.

The coupler 30A includes a variable capacitor 51. The variable capacitor 51 is disposed in the housing 30h. The variable capacitor 51 is a variable condenser. The variable capacitor 51 includes a stationary electrode 51s, a rotary electrode 51r, and a rotary shaft 51a. The rotary shaft 51a may include an insulating coupler 51i disposed between an electrode group including the stationary electrode 51s and the rotary electrode 51r, and a driver 34d. The rotary shaft 51a extends, for example, in a vertical direction, and is supported rotatably around a central axis line thereof. Further, the rotary shaft 51a may extend in another direction such as a horizontal direction.

The stationary electrode 51s is fixed so as not to move, and is disposed substantially parallel to the rotary electrode 51r. The stationary electrode 51s is grounded. The rotary electrode 51r has a fan shape or a semicircular shape, and is coupled to the rotary shaft 51a to be able to rotate with the rotary shaft 51a. The rotary electrode 51r is connected to a coupling rod 40r via a connection plate 51cp formed of a conductor. Further, the variable capacitor 51 may include a plurality of stationary electrodes 51s and a plurality of rotary electrodes 51r, which are alternately arranged.

The coupler 30A may further include the driver 34d such as a motor (e.g., a stepping motor) and a controller 34c. The driver 34d and the controller 34c may be disposed in the housing 30h. The driver 34d rotates the rotary shaft 51a and the rotary electrode 51r according to an electrical signal from the controller 34c. To the controller 34c, a rotation angle position of the rotary electrode 51r for reducing a power level of reflected waves is notified from the power controller 24c. The controller 34c controls the driver 34d to adjust a rotation angle position of the rotary electrode 51r to the notified rotation angle position. Accordingly, the variable capacitor 51 is capable of adjusting a capacitance (electrostatic capacity) thereof.

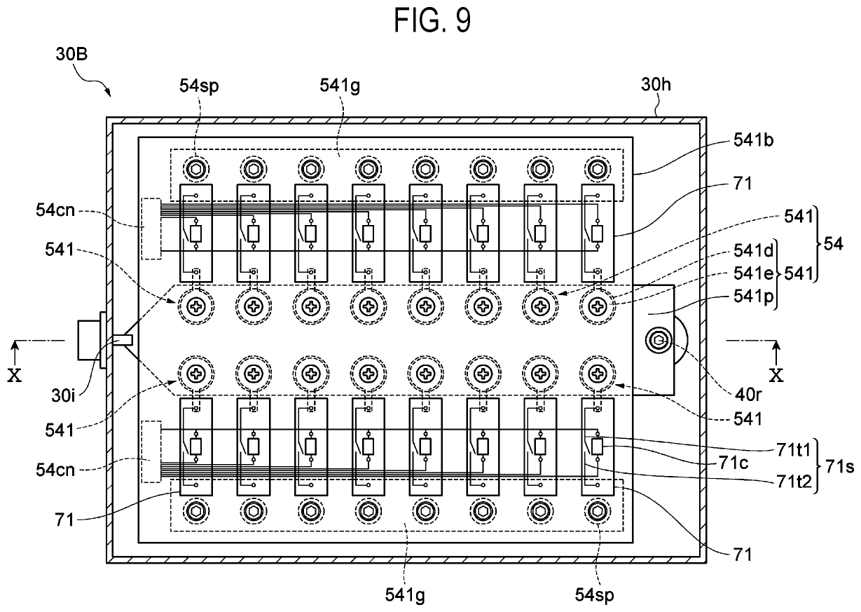

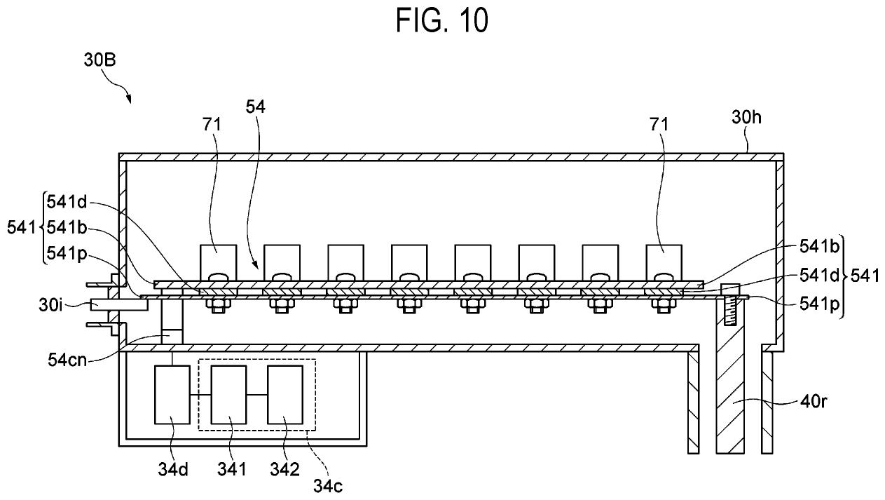

A coupler according to another exemplary embodiment of the present disclosure, which can be employed as the coupler 30 of the plasma processing apparatus 1C, is described below with reference to FIGS. 9 and 10. FIG. 9 is a cross-sectional view illustrating the coupler according to another exemplary embodiment. FIG. 10 is a cross-sectional view taken along line X-X of FIG. 9.

In a coupler 30B illustrated in FIGS. 9 and 10, a radio-frequency supply line 40 is constituted as a coupling rod 40r extending upwardly from the power feeder 20p. A matching circuit 34 in the coupler 30B includes a variable capacitor 54 instead of the variable capacitor 51. The variable capacitor 54 includes a plurality of capacitor elements 541. The plurality of capacitor elements 541 are arranged to form one or more columns. In an illustrated example, the plurality of capacitor elements 541 form two columns.

The matching circuit 34 of the coupler 30B includes a printed board 541b, a capacitor plate 541p, and a plurality of dielectric members 541d. The printed board 541b, the capacitor plate 541p, and the plurality of dielectric members 541d are provided in a housing 30h.

The printed board 541b is provided in the housing 30h and extends horizontally. The printed board 541b may have a substantially rectangular shape. The printed board 541b is provided with a plurality of capacitor patterns 541e and a ground pattern 541g in a lower surface thereof. The plurality of capacitor patterns 541e and the ground pattern 541g are formed of a metal such as copper. The plurality of capacitor patterns 541e have a substantially circular shape. The plurality of capacitor patterns 541e are arranged to form the above-described one or more columns (the two columns in the illustrated example). The ground pattern 541g is connected to a bottom portion of the housing 30h, i.e., a ground via a plurality of metal supports 54sp.

The capacitor plate 541p extends horizontally below the printed board 541b so as to face the plurality of capacitor patterns 541e. The capacitor plate 541p may have a rectangular shape. The capacitor plate 541p extends between an input unit 30i of radio-frequency power and the coupling rod 40r in the coupler 30B, and connects the radio-frequency power source 24 to the power feeder 20p via the radio-frequency supply line 40 (i.e., the coupling rod 40r).

Each of the plurality of dielectric members 541d is fitted and fixed by using a screw between a corresponding capacitor pattern among the plurality of capacitor patterns 541e and the capacitor plate 541p. The plurality of dielectric members 541d may be formed of polytetrafluoroethylene or the like, and may have a ring shape. Each of the plurality of capacitor elements 541 described above is constituted by one capacitor pattern among the plurality of capacitor patterns 541e, the capacitor plate 541p, and a dielectric member disposed therebetween among the plurality of dielectric members 541d.

The plurality of capacitor patterns 541e may have a same area. In this case, the plurality of capacitor elements 541 have a same capacitance (electrostatic capacity). Further, an edge of each of the plurality of capacitor patterns 541e may have a size slightly smaller than a size of a corresponding dielectric member among the plurality of dielectric members 541d so as to be located inside an edge of the corresponding dielectric member. Accordingly, it is possible to suppress creeping discharge.

The matching circuit 34 in the coupler 30B further includes a plurality of relays 71. Each of the plurality of relays 71 includes a relay switch 71s and a relay coil 71c. The relay switch 71s includes a first contact point 71t1 and a second contact point 71t2, and by a state (opening or closing) thereof, switches between cutoff and connection between the first contact point 71t1 and the second contact point 71t2. The first contact point 71t1 of the relay switch 71s of each of the plurality of relays 71 is connected to a corresponding capacitor pattern among the plurality of capacitor patterns 541e. Further, the second contact point 71t2 of the relay switch 71s of each of the plurality of relays 71 is connected to the ground pattern 541g.

In the coupler 30B, a driver 34d is constituted as a relay driving circuit for driving each of the plurality of relays 71, and is connected to the relay coil 71c of each of the plurality of relays 71 via a connector 54cn. The driver 34d is configured to apply a DC voltage signal for setting a state (opening state or closing state) of the relay switch 71s of each of the plurality of relays 71 to the relay coil 71c of each of the plurality of relays 71.

Like the controller 34c of the coupler 30A, a controller 34c includes a control circuit 341 and a communication circuit 342. The control circuit 341 is capable of communicating with the power controller 24c via the communication circuit 342. To the control circuit 341, a capacitance set value of the variable capacitor 54 for reducing a power level of reflected waves is notified from the power controller 24c via the communication circuit 342. To set a capacitance of the variable capacitor 54 to the notified set value, the control circuit 341 controls the driver 34d (i.e., the relay driving circuit) to set a state of the relay switch 71s of each of the plurality of relays 71.

Various exemplary embodiments have been described above, but the present disclosure is not limited to the aforementioned exemplary embodiments, and various additions, omissions, substitutions, and changes may be made. The components in the different embodiments may be combined to form another embodiment.

Hereinafter, various exemplary embodiments included in the present disclosure are described in the following [E1] to [E12].

### [E1]

A plasma processing apparatus, including:

a chamber;

an introducer disposed to introduce electromagnetic waves into a plasma generation region in the chamber;

a radio-frequency power source;

a radio-frequency supply line electrically connected to the radio-frequency power source;

and a resonator including a power feeder which is an entrance of electromagnetic waves and is connected to the radio-frequency supply line, a first end and a second end, which are configured to resonate the electromagnetic waves therebetween, and a waveguide extending between the first end and the second end to be electromagnetically coupled to the introducer, wherein a distance between the power feeder and the first end along a propagation direction of the electromagnetic waves is shorter than a distance along the propagation direction between the first end and a position in the resonator at which, during plasma excitation, an impedance obtained when viewing a load side from the position becomes equal to a characteristic impedance of the radio-frequency supply line.

### [E2]

The plasma processing apparatus of E1, further including a capacitor disposed to suppress reflection of radio-frequency power in the power feeder.

### [E3]

The plasma processing apparatus of E2, wherein the radio-frequency supply line includes a coaxial line, and
wherein the capacitor includes a dielectric member disposed between an inner conductor and an outer conductor of the coaxial line.

### [E4]

The plasma processing apparatus of E2, wherein the radio-frequency supply line includes a coaxial line,
wherein the capacitor includes a plurality of condensers electrically connected between an inner conductor and an outer conductor of the coaxial line, and
wherein the plurality of condensers are arranged circumferentially around the inner conductor.

### [E5]

The plasma processing apparatus of E1, further including a circulator including a first port connected to the radio-frequency power source, a second port connected to the radio-frequency supply line, and a third port connected to a load, or an isolator.

### [E6]

The plasma processing apparatus of E1, further including a coupler which includes an input unit of radio-frequency power generated by the radio-frequency power source, has a variable impedance, and is connected between the radio-frequency power source and the power feeder.

### [E7]

The plasma processing apparatus of E6, wherein the coupler includes a variable capacitor configured to provide the variable impedance.

### [E8]

The plasma processing apparatus of E7, wherein the radio-frequency supply line includes a coupling rod electrically connected between the radio-frequency power source and the power feeder, and
wherein the variable capacitor is electrically connected between the coupling rod and a ground.

### [E9]

The plasma processing apparatus of E7 or E8, wherein the variable capacitor includes:
a plurality of capacitor elements electrically connected to the radio-frequency supply line; and
a plurality of relays each including a relay switch including a first contact point connected to a corresponding capacitor element among the plurality of capacitor elements and a second contact point connected to a ground, and a relay coil.

### [E10]

The plasma processing apparatus of E9, wherein the variable capacitor further includes:
a capacitor plate connected to the radio-frequency supply line;
a printed board which has a plurality of capacitor patterns and has the plurality of relays mounted thereon; and
a plurality of dielectric members each disposed between a corresponding capacitor pattern among the plurality of capacitor patterns and the capacitor plate,
wherein each of the plurality of capacitor elements is constituted by the capacitor plate, a corresponding capacitor pattern among the plurality of capacitor patterns, and a dielectric member among the plurality of dielectric members disposed between the capacitor plate and the corresponding capacitor pattern.

### [E11]

The plasma processing apparatus of E10, wherein the plurality of capacitor elements have a same electrostatic capacity.

### [E12]

The plasma processing apparatus of any one of E1 to E11, wherein the resonator includes:
an inner periphery extending around a central axis line of the chamber and the resonator;
an outer periphery extending around the central axis line;
the waveguide having a layered structure alternately folded between the inner periphery and the outer periphery;
an upper portion which is located in an uppermost layer of the layered structure and provides the first end in the outer periphery; and
a lower portion which is located in a lowermost layer of the layered structure, provides the second end in the outer periphery, and provides a plurality of slots which couple the waveguide and the introducer to each other along the second end.

According to the present disclosure in some embodiments, it is possible to suppress hormonic waves returning to the radio-frequency power source of the plasma processing apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A plasma processing apparatus, comprising:
a chamber;
an introducer disposed to introduce electromagnetic waves into a plasma generation region in the chamber;
a radio-frequency power source;
a radio-frequency supply line electrically connected to the radio-frequency power source; and
a resonator including a power feeder which is an entrance of electromagnetic waves and is connected to the radio-frequency supply line, a first end and a second end, which are configured to resonate the electromagnetic waves therebetween, and a waveguide extending between the first end and the second end to be electromagnetically coupled to the introducer,
wherein a distance between the power feeder and the first end along a propagation direction of the electromagnetic waves is shorter than a distance along the propagation direction between the first end and a position in the resonator at which, during plasma excitation, an impedance obtained when viewing a load side from the position becomes equal to a characteristic impedance of the radio-frequency supply line.

2. The plasma processing apparatus of claim 1, further comprising a capacitor disposed to suppress reflection of radio-frequency power in the power feeder.

3. The plasma processing apparatus of claim 2, wherein the radio-frequency supply line includes a coaxial line, and
wherein the capacitor includes a dielectric member disposed between an inner conductor and an outer conductor of the coaxial line.

4. The plasma processing apparatus of claim 3, wherein the resonator includes:
an inner periphery extending around a central axis line of the chamber and the resonator;
an outer periphery extending around the central axis line;
the waveguide having a layered structure alternately folded between the inner periphery and the outer periphery;
an upper portion which is located in an uppermost layer of the layered structure and provides the first end in the outer periphery; and
a lower portion which is located in a lowermost layer of the layered structure, provides the second end in the outer periphery, and provides a plurality of slots which couple the waveguide and the introducer to each other along the second end.

5. The plasma processing apparatus of claim 2, wherein the radio-frequency supply line includes a coaxial line,
wherein the capacitor includes a plurality of condensers electrically connected between an inner conductor and an outer conductor of the coaxial line, and
wherein the plurality of condensers are arranged circumferentially around the inner conductor.

6. The plasma processing apparatus of claim 1, further comprising a circulator including a first port connected to the radio-frequency power source, a second port connected to the radio-frequency supply line, and a third port connected to a load, or an isolator.

7. The plasma processing apparatus of claim 1, further comprising a coupler which includes an input unit of radio-frequency power generated by the radio-frequency power source, has a variable impedance, and is connected between the radio-frequency power source and the power feeder.

8. The plasma processing apparatus of claim 7, wherein the coupler includes a variable capacitor configured to provide the variable impedance.

9. The plasma processing apparatus of claim 8, wherein the radio-frequency supply line includes a coupling rod electrically connected between the radio-frequency power source and the power feeder, and
wherein the variable capacitor is electrically connected between the coupling rod and a ground.

10. The plasma processing apparatus of claim 8, wherein the variable capacitor includes:
a plurality of capacitor elements electrically connected to the radio-frequency supply line; and
a plurality of relays each including a relay switch including a first contact point connected to a corresponding capacitor element among the plurality of capacitor elements and a second contact point connected to a ground, and a relay coil.

11. The plasma processing apparatus of claim 10, wherein the variable capacitor further includes:
a capacitor plate connected to the radio-frequency supply line;
a printed board which has a plurality of capacitor patterns and has the plurality of relays mounted thereon; and
a plurality of dielectric members each disposed between a corresponding capacitor pattern among the plurality of capacitor patterns and the capacitor plate,
wherein each of the plurality of capacitor elements is constituted by the capacitor plate, a corresponding capacitor pattern among the plurality of capacitor patterns, and a dielectric member among the plurality of dielectric members disposed between the capacitor plate and the corresponding capacitor pattern.

12. The plasma processing apparatus of claim 11, wherein the plurality of capacitor elements have a same electrostatic capacity.

13. The plasma processing apparatus of claim 1, wherein the resonator includes:
an inner periphery extending around a central axis line of the chamber and the resonator;
an outer periphery extending around the central axis line;
the waveguide having a layered structure alternately folded between the inner periphery and the outer periphery;
an upper portion which is located in an uppermost layer of the layered structure and provides the first end in the outer periphery; and
a lower portion which is located in a lowermost layer of the layered structure, provides the second end in the outer periphery, and provides a plurality of slots which couple the waveguide and the introducer to each other along the second end.
